(19) United States
(12) Patent Application Publication
(10) Pub. No.: US 2009/0298284 A1
(43) Pub. Date: Dec. 3, 2009

(54) METHOD FOR PREPARING INTEGRATED CIRCUIT STRUCTURE WITH POLYMORPHOUS MATERIAL

(75) Inventors: TZU LUN CHENG, TAICHUNG CITY (TW); CHENG DA WU, KEELUNG CITY (TW); DA YU CHUANG, CHANGHUA COUNTY (TW); WEI HENG LEE, TAICHUNG CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/128,434

(22) Filed: May 28, 2008

(51) Int. Cl. H01L 21/44

(52) U.S. Cl. 438/664; 257/E21.476

(57) ABSTRACT

A method for preparing an integrated circuit structure performs a deposition process to form a precursor layer on a substrate, and the precursor layer has a phase transition property in a transition temperature region. Subsequently, a first thermal treating process is performed at a first temperature to transform the precursor layer into a polymorphous layer possessing a predetermined crystalline phase, and the first temperature is higher than an upper limit of the temperature of the transition temperature region.

### BACKGROUND OF THE INVENTION

(A) Field of the Invention

The present invention relates to a method for preparing an integrated circuit structure with polymorphous material, and more particularly, to a method for preparing an integrated circuit structure with polymorphous material using rapid thermal annealing technique such that the polymorphous material possesses a predetermined crystalline phase with lower resistance.

(B) Description of the Related Art

Polymorphous material such as titanium silicide has become the most widely used silicide in the integrated circuit structure for self-aligned silicide applications due to its combined characteristics of very low resistance, self-aligning ability, and relatively good thermal stability. However, titanium silicide has a tendency during processing at higher temperatures to agglomerate into two different phases, C54 and C49, which have different lattice structures. The titanium silicide phase formed at higher temperatures, C54, is more stable and has a much lower resistance than the C49 metastable phase formed at lower temperatures.

When using the widely-accepted processing conditions for preparing titanium silicide, the less-desirable, higher-resistance C49 phase is formed first. To obtain the lower-resistance C54 phase from the higher-resistance C49 phase requires another high-temperature annealing process, which is disadvantageous because it can have detrimental effects on the silicide and other integrated circuit elements, especially at smaller line-widths. For example, the increasing use of dual-doped polysilicon gate structures in some devices has increased their sensitivity to additional heat cycles, which are required by the second annealing step. Also, silicon nitride peeling and cracking have been associated with the second annealing step.

In addition, the rapid thermal annealing (RTA) machine is used to perform the thermal treating of the titanium silicide. Most RTA machines use a pyrometer as the temperature sensor, which detects the temperature of the object based on its optical properties such as emissivity, absorptivity and reflectivity; however, these optical properties are influenced by the reflection index of the films on the wafer. Obtaining the lower-resistance C54 phase from the higher-resistance C49 phase by the rapid thermal annealing causes the object to undergo a phase transition, which causes the reflection and emissivity to vary while the temperature rises. Consequently, the pyrometer cannot accurately detect the actual temperature nor precisely control temperature, and a temperature overshooting occurs, i.e., the wafer is overheated. Thus, there is a need for an improved method for preparing the C54 phase titanium silicide without overheating.

U.S. Pat. No. 6,121,061 to Franciscus et al discloses a method of processing a wafer in a semiconductor processing chamber. The prior art describes that its temperature control is via thermal couple (PID controller) and this method is not influenced by material phase transition, so the prior art does not solve the problem arose from material phase transition.

### SUMMARY OF THE INVENTION

One aspect of the present invention provides a method for preparing an integrated circuit structure with polymorphous material using rapid thermal annealing technique such that the polymorphous material possesses a predetermined crystalline phase with lower resistance.

A method for preparing an integrated circuit structure according to this aspect of the present invention performs a deposition process to form a precursor layer on substrate, and the precursor layer has a phase transition property in a transition temperature region. Subsequently, a first thermal treating process is performed at a first temperature to transform the precursor layer into a polymorphous layer possessing a predetermined crystalline phase, and the first temperature is higher than an upper limit of the temperature in the transition temperature region.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 4 illustrate a method for preparing an integrated circuit structure according to one embodiment of the present invention.

### DETAILED DESCRIPTION OF THE INVENTION

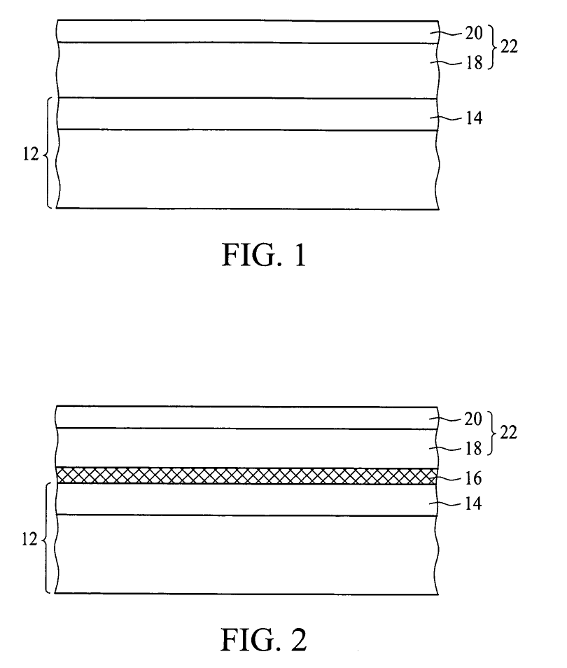

FIG. 1 to FIG. 4 illustrate a method for preparing an integrated circuit structure 10 according to one embodiment of the present invention. A deposition process is performed to form an interface structure 22 on a substrate 12 with a silicon-containing layer 14 such as a monocrystalline silicon layer or a polysilicon layer. The interface structure 22 may include a titanium layer 18 on the silicon-containing layer 14 and a titanium nitride layer 20 on the titanium layer 18. In particular, the silicon-containing layer 14 and the titanium layer 18 react to form a precursor layer 16 on the substrate 12, as shown in FIG. 2. The precursor layer 16 can be a C49 phase titanium silicide layer including titanium and silicon and having a phase transition property in a transition temperature region between 740 and 770° C.

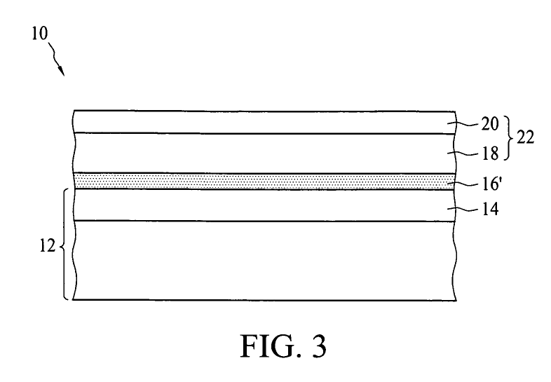

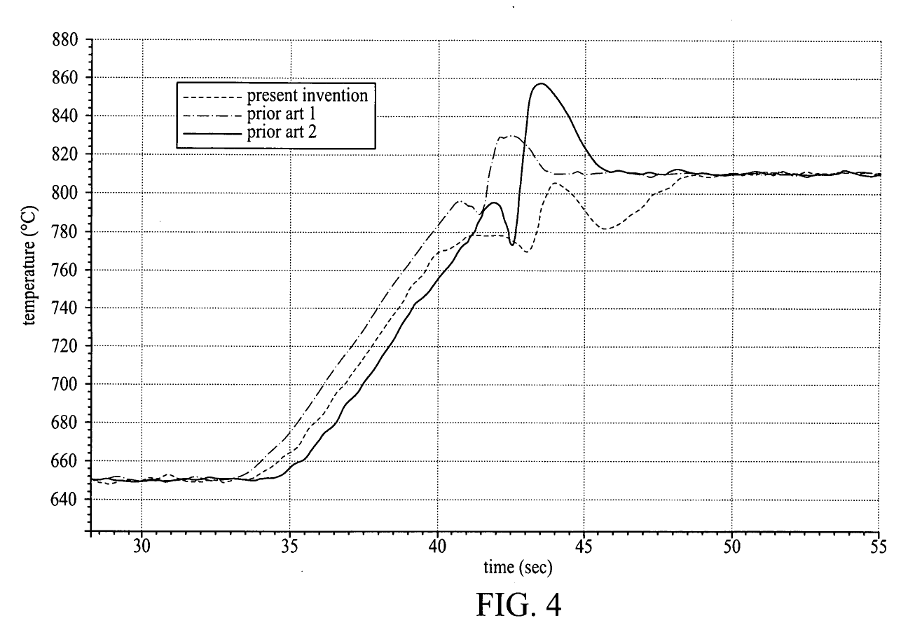

Referring to FIG. 3, a first thermal treating process is performed at a first temperature for a predetermined duration at least 3 seconds to transform the precursor layer 16 into a polymorphous layer 16′ possessing a predetermined crystalline phase. The predetermined duration is between 3 and 10 seconds, preferable between 3 and 7 seconds, more preferable 5 seconds, and the first temperature is higher than 770° C., which is higher than an upper limit of the transition temperature of titanium silicide layer between 740 and 770° C. In particular, the first thermal treating process transforms the C49 phase titanium silicide layer with a higher resistance into a C54 phase titanium silicide layer with a relatively lower resistance. The temperature control in the first temperature process depends on the desired property of the precursor layer, for example, to attend the purpose of reduce contact resistance during the storage node formation, the first temperature process is proposed to be between 775 and 800° C., preferably between 775 and 790° C., more preferably between 777 and 783° C. Subsequently, a second thermal treating process is performed at a second temperature to densify the interface structure 22, and the second temperature is preferably 810° C. if the first temperature is about 800° C. Referring to FIG. 4, the first thermal treating process at the first temperature between 777 and 783° C. can be considered as a pre-heating (pre-soak) process before the second thermal treating (soak) process at the second temperature substantially of 810° C. to actually densify the interface structure 22. The prior art 1 and the prior art 2 do not use a pre-heating process, i.e. the prior arts directly heat the C49 phase titanium silicide layer to 810° C., and there is obviously a temperature overshoot phenomenon above 810° C. due to the phase transition property, which causes leakage problems. In contrast, the present invention uses the first thermal treating process at the first temperature between 777 and 783° C. as the pre-heating process of the second thermal treating process at the second temperature substantially of 810° C., and the phase transition of the C49 phase titanium silicide layer is completed during the first thermal treating process. Consequently, there is no temperature overshoot phenomenon above 810° C. due to the phase transition property according to the present invention.

The precursor layer 16 may include cobalt and silicon, and the first thermal treating process may be performed at the first temperature between 545 and 555° C. to transform the precursor layer 16 into a cobalt silicide layer. Furthermore, the precursor layer 16 may include tungsten and silicon, and the first thermal treating process is performed at the first temperature between 597 and 603° C. to transform the precursor layer 16 into a tungsten silicide layer. In cases where the precursor layer 16 includes silicon only, the first thermal treating process can be performed at the first temperature below 580° C. to transform the precursor layer 16 into an amorphous silicon layer; in contrast, the first thermal treating process can also be performed at the first temperature above 580° C. to transform the precursor layer 16 into a polysilicon layer.

In general, it is believed that the polymorphous material according to the method of the present invention may be any material possessing the phase transition property. For the purposes of this application, “polymorphous material” is defined to include, without limitation, the following preferred metals: titanium (Ti), cobalt (Co), molybdenum (Mo), vanadium (V), tungsten (W), tantalum (Ta), niobium (Nb), or Chromium (Cr). The above metals should in general work with any of the herein disclosed manners of disposition. In addition, the term “transition temperature region” is determined by many experimental results of resistance change during rapid thermal annealing. While the phase transition is processing, the material resistance will be increased. After the precursor layer is almost transformed into a predetermined crystalline phase, the resistance will be down and does not change by temperature until agglomeration. Therefore, the material resistance in the transition temperature region is usually not uniform.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for preparing an integrated circuit structure, comprising the steps of:
forming a precursor layer on a substrate, the precursor layer having a phase transition property in a transition temperature region; and
performing a first thermal treating process at a first temperature for a predetermined duration when the precursor layer transforms into a predetermined crystalline phase, with the first temperature being higher than an upper limit of the temperature in the transition temperature region.

2. The method for preparing an integrated circuit structure of claim 1, wherein the substrate includes a silicon-containing layer.

3. The method for preparing an integrated circuit structure of claim 1, wherein the precursor layer includes titanium and silicon.

4. The method for preparing an integrated circuit structure of claim 1, wherein the first thermal treating process transforms the precursor layer into a C54 phase titanium silicide layer.

5. The method for preparing an integrated circuit structure of claim 1, wherein the first temperature is detected by a pyrometer that is sensitive to light property change of the integrated circuit structure.

6. The method for preparing an integrated circuit structure of claim 4, wherein the transition temperature region is between 740 and 770° C.

7. The method for preparing an integrated circuit structure of claim 1, further comprising a step of performing a second thermal treating process at a second temperature to densify the interface structure, and the second temperature is higher than the first temperature.

8. The method for preparing an integrated circuit structure of claim 1, wherein the precursor layer includes cobalt and silicon.

9. The method for preparing an integrated circuit structure of claim 8, wherein the first thermal treating process is performed at the first temperature between 545 and 555° C.

10. The method for preparing an integrated circuit structure of claim 9, wherein the first thermal treating process transforms the precursor layer into a cobalt silicide layer.

11. The method for preparing an integrated circuit structure of claim 1, wherein the precursor layer includes tungsten and silicon.

12. The method for preparing an integrated circuit structure of claim 11, wherein the first thermal treating process is performed at the first temperature between 597 and 603° C.

13. The method for preparing an integrated circuit structure of claim 12, wherein the first thermal treating process transforms the precursor layer into a tungsten silicide layer.

14. The method for preparing an integrated circuit structure of claim 2, before forming the precursor layer, the method further comprising: depositing a layer with polymorphous material on the silicon-containing layer, thereby forming a precursor layer between the layer with polymorphous material and the silicon-containing layer.

15. The method for preparing an integrated circuit structure of claim 12, wherein the first thermal treating process is performed at the first temperature below 580° C.

16. The method for preparing an integrated circuit structure of claim 15, wherein the first thermal treating process transforms the precursor layer into an amorphous silicon layer.

17. The method for preparing an integrated circuit structure of claim 14, wherein the first thermal treating process is performed at the first temperature above 580° C.

18. The method for preparing an integrated circuit structure of claim 17, wherein the first thermal treating process transforms the precursor layer into a polysilicon layer.

19. The method for preparing an integrated circuit structure of claim 1, wherein the predetermined duration is between 3 and 7 seconds.
